(19) United States
(12) Patent Application Publication
(10) Pub. No.: US 2017/0233248 A1
(43) Pub. Date: Aug. 17, 2017

(54) MICRO SENSOR AND MANUFACTURING METHOD THEREOF

(71) Applicant: GlobalMEMS Co., Ltd., Grand Cayman (KY)

(72) Inventors: Hsi-Wen Tung, Taipei City (TW); Ming-Ching Wu, Taoyuan City (TW)

(21) Appl. No.: 15/132,239

(22) Filed: Apr. 19, 2016

(30) Foreign Application Priority Data
Feb. 16, 2016 (TW) 105104421

(51) Int. Cl. B81B 7/02; B81C 1/00

(52) U.S. Cl. CPC B81B 7/02; B81C 1/00301; B81B 2201/0264; B81B 2201/0278; B81B 2207/092; B81B 2207/07; B81B 2203/0315; B81C 2201/019; B81C 2201/0132; B81C 2201/0176

(57) ABSTRACT

A micro sensor including a first substrate and a second substrate is provided. The first substrate has a surface with a cavity. The second substrate has a sensing structure. The surface of the first substrate with the cavity is bonded to the second substrate to seal the cavity, such that a pressure value in the cavity is a constant value. A manufacturing method thereof is also provided.

### CROSS-REFERENCE TO RELATED APPLICATION

This application claims the priority benefit of Taiwan application serial no. 105104421, filed on Feb. 16, 2016. The entirety of the above-mentioned patent application is hereby incorporated by reference herein and made a part of this specification.

### BACKGROUND

Field of the Invention

The invention relates to a micro-electro-mechanical system (MEMS) apparatus and a manufacturing method thereof and more particularly, to a micro sensor and a manufacturing method thereof.

Description of Related Art

A micro-electro-mechanical system (MEMS) technique refers to a design based on a miniaturized electro-mechanical integrated structure. At present, the common MEMS technique is mainly applied in three major fields, i.e., micro sensor, micro actuator and micro structure elements. Among them, the micro sensor can be used to convert external environmental changes (e.g., sounds, pressures, speeds, etc.) into electric signals (e.g., voltages or currents), thereby achieving environmental sensing functions, such as sound sensing, pressure sensing, acceleration sensing and so on. The micro sensor may be manufactured by using a semiconductor fabrication process and integrated with an integrated circuit, thus has preferable competitiveness. Accordingly, the design and manufacture of the micro sensor in fact become the development trend of MEMS.

### SUMMARY

The invention provides a manufacturing method of a micro sensor by which a micro sensor with environmental sensing capability is manufactured.

The invention provides a micro sensor at least capable of sensing an external pressure change.

According to an embodiment of the invention, a manufacturing method of a micro sensor is provided, which includes steps as follow. A cavity is formed on a surface of a first substrate. The surface of the first substrate with the cavity is bonded to a second substrate to seal the cavity, such that a pressure value in the cavity is a constant value. A sensing structure is formed in the second substrate.

In an embodiment of the invention, before the first substrate is bonded to the second substrate, the manufacturing method of the micro sensor further includes steps as follow. An insulation layer is formed on the first substrate or the second substrate. After the first substrate is bonded to the second substrate, at least part of the insulation layer is located between the first substrate and the second substrate, and the at least part of the insulation layer at least covers the surface with the cavity and the cavity.

In an embodiment of the invention, a method of forming the sensing structure in the second substrate includes steps as follow. A plurality of connection portions are formed in the second substrate. A plurality of pressure sensing elements are formed in the second substrate. Each of the pressure sensing elements is connected with two adjacent connection portions, and orthographic projections of the pressure sensing elements on the first substrate fall within a range covered by the cavity.

In an embodiment of the invention, a method of forming the sensing structure in the second substrate further includes steps as follow. At least one temperature sensing element is formed in the second substrate. The at least one temperature sensing element is connected with the connection portions.

In an embodiment of the invention, a method of forming the connection portions, the pressure sensing elements and the at least one temperature sensing element include ion doping, a doping concentration of each of the pressure sensing elements is less than a doping concentration of each of the connection portions, and the doping concentration of each of the pressure sensing elements is higher than or equal to a doping concentration of the at least one temperature sensing element.

In an embodiment of the invention, after the connection portions, the pressure sensing elements and the at least one temperature sensing element are formed, the manufacturing method of forming the micro sensor further includes steps as follow. A first inter-layer dielectric layer is formed on the second substrate. The connection portions, the pressure sensing elements and the at least one temperature sensing element are located between the first inter-layer dielectric layer and the insulation layer. The first inter-layer dielectric layer has a plurality of first openings. Each of the first openings exposes a portion of one of the connection portions. A plurality of conductive wires are formed on the first inter-layer dielectric layer. The portion of each of the connection portions is connected with one of the conductive wires. A second inter-layer dielectric layer is formed on the first inter-layer dielectric layer and the conductive wires. The second inter-layer dielectric layer has a plurality of second openings. Each of the second openings exposes a portion of one of the conductive wires. A plurality of pads are formed on the second inter-layer dielectric layer. Each of the pads is connected with the portion of the corresponding conductive wire through one of the second openings.

According to an embodiment of the invention, a micro sensor including a first substrate and a second substrate is provided. The first substrate has a surface with a cavity. The second substrate has a sensing structure. The surface of the first substrate with the cavity is bonded to the second substrate to seal the cavity, such that a pressure value in the cavity is a constant value.

In an embodiment of the invention, the micro sensor further includes an insulation layer. The insulation layer is disposed on the first substrate or the second substrate. At least part of the insulation layer is located between the first substrate and the second substrate, and the at least part of the insulation layer at least covers the surface with the cavity and the cavity.

In an embodiment of the invention, the sensing structure includes a plurality of connection portions and a plurality of pressure sensing elements. Each of the pressure sensing elements is connected with two adjacent connection portions, and orthographic projections of the pressure sensing elements on the first substrate fall within a range covered by the cavity.

In an embodiment of the invention, the sensing structure further includes at least one temperature sensing element. The at least one temperature sensing element is connected with the connection portions.

In an embodiment of the invention, the connection portions, the pressure sensing elements and the at least one temperature sensing element are formed by means of ion doping, a doping concentration of each of the pressure sensing elements is less than a doping concentration of each of the connection portions, and the doping concentration of each of the pressure sensing elements is higher than or equal to a doping concentration of the at least one temperature sensing element.

In an embodiment of the invention, the micro sensor further includes a first inter-layer dielectric layer, a plurality of conductive wires, a second inter-layer dielectric layer and a plurality of pads. The first inter-layer dielectric layer is disposed on the second substrate. The connection portions, the pressure sensing elements and the at least one temperature sensing element are located between the first inter-layer dielectric layer and the insulation layer. The first inter-layer dielectric layer has a plurality of first openings. Each of the first openings exposes a portion of one of the connection portions. The conductive wires are disposed on the first inter-layer dielectric layer. The portion of each of the connection portions is connected with one of the conductive wires. The second inter-layer dielectric layer is disposed on the first inter-layer dielectric layer and the conductive wires, and the second inter-layer dielectric layer has a plurality of second openings. Each of the second openings exposes a portion of one of the conductive wires. The pads are disposed on the second inter-layer dielectric layer. Each of the pads is connected with the portion of the corresponding conductive wire through one of the second openings.

To sum up, in the embodiments of the invention, the sealed cavity is formed between the first substrate and the second substrate, and the second substrate having the sensing structure is disposed on the cavity. When an external pressure change occurs, the second substrate having the sensing structure is deformed due to a difference between inner and external pressures occurring to the cavity, such that the sensing structure can measure different physical quantities. Therefore, the micro sensor of the invention is capable of sensing the external pressure change. The invention also provides a manufacturing method of the micro sensor.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a micro sensor according to an embodiment of the invention.

FIGS. 2A to 2K are schematic cross-sectional views illustrating a manufacturing process of a micro sensor according to an embodiment of the invention.

FIG. 3 is a schematic top view of a micro sensor according to another embodiment of the invention.

FIGS. 4A to 4F are partial schematic cross-sectional views illustrating a manufacturing process of a micro sensor according to another embodiment of the invention.

### DESCRIPTION OF EMBODIMENTS

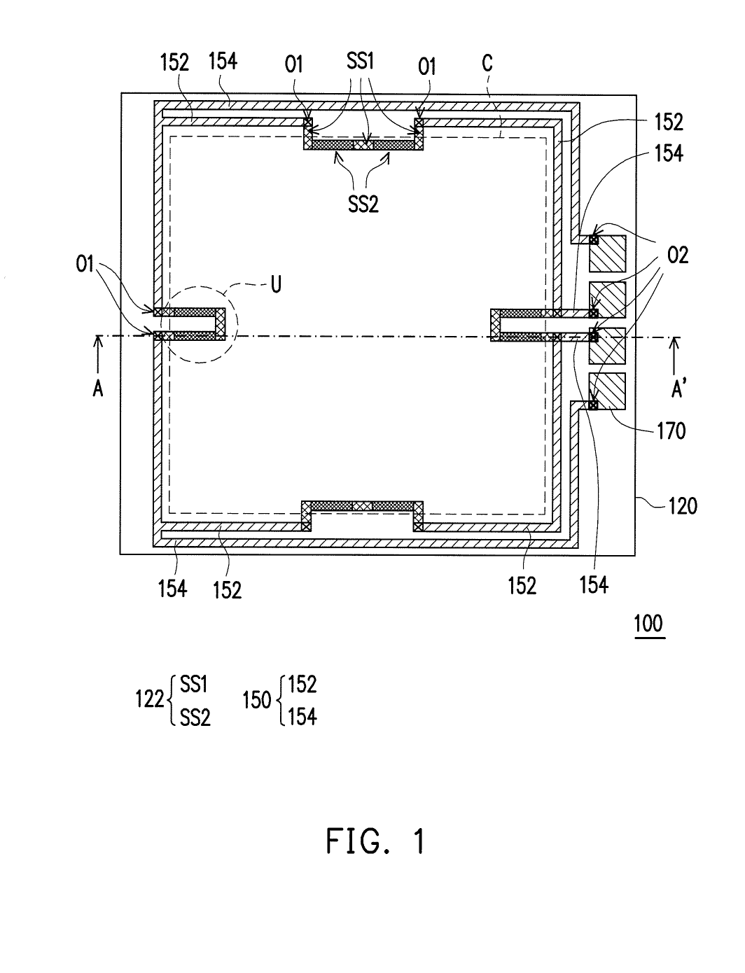

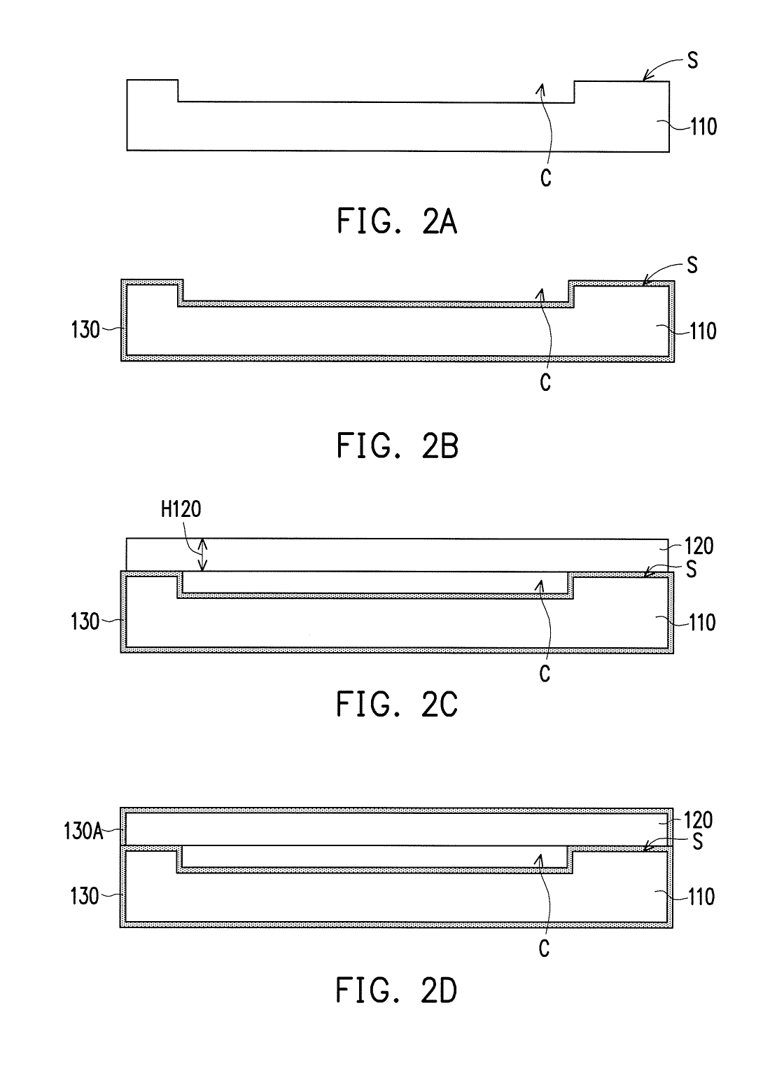

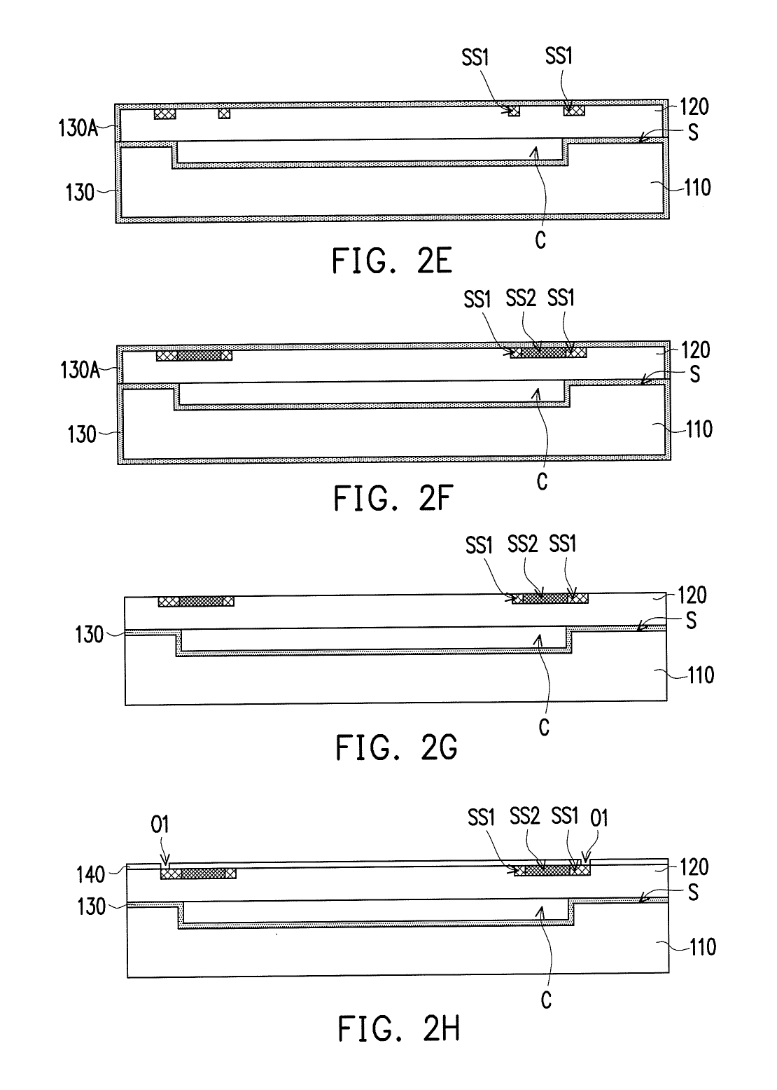

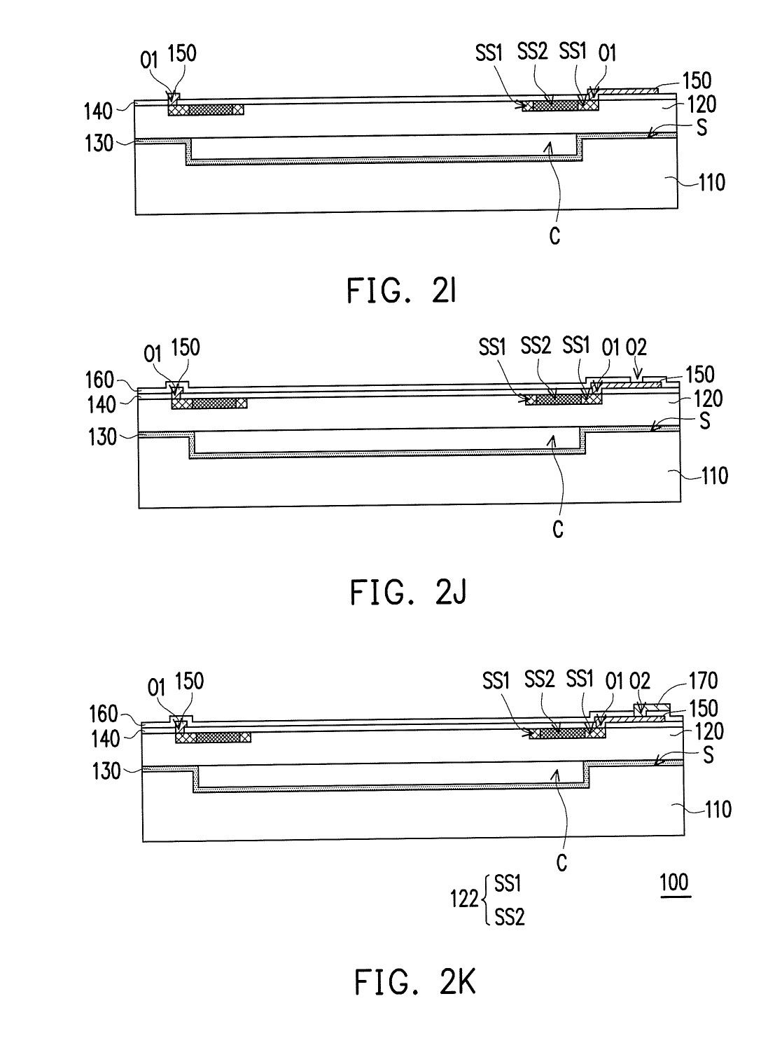

FIG. 1 is a schematic top view of a micro sensor according to an embodiment of the invention. FIGS. 2A to 2K are schematic cross-sectional views illustrating a manufacturing process of a micro sensor according to an embodiment of the invention, and the sections illustrated in FIGS. 2A to 2K are corresponding to a section line A-A′ in FIG. 1. In order to illustrate a sensing structure of a micro sensor clearly, part of film layers of the micro sensor are omitted in FIG. 1. Thus, the specific stacking structure of the micro sensor may refer to FIG. 2K.

Referring to FIGS. 1 and 2K first, a micro sensor 100 includes a first substrate 110 and a second substrate 120. The first substrate 110 has a surface S with a cavity C formed thereon. The second substrate 120 has a sensing structure 122. The surface S of the first substrate 110 with the cavity C is bonded to the second substrate 120 to seal the cavity C, such that a pressure value in the cavity C is a constant value.

In the present embodiment, the sensing structure 122 is used to, for example, sense an external pressure change, and the sensing structure 122 may include a plurality of connection portions SS1 and a plurality of pressure sensing elements SS2. Each of the pressure sensing elements SS2 is connected with two adjacent connection portions SS1, and orthographic projections of the pressure sensing elements SS2 on the first substrate 110 fall within a range (e.g., a range presented in dashed lines in FIG. 1) covered by the cavity.

Specifically, the pressure sensing elements SS2 are, for example, piezoresistive pressure sensing elements, and the pressure sensing elements SS2 are disposed at four sides of the second substrate 120. The pressure sensing elements SS2 located at opposite sides are disposed in a mirror image manner. In the present embodiment, each side of the second substrate 120 has a sensing unit U composed of two pressure sensing elements SS2 and three connection portions SS1. However, the numbers and the disposition relation of the pressure sensing elements SS2 and the connection portions SS1 of each sensing unit U may vary with demands and are not limited to those illustrated in FIG. 1.

Based on different design demands, the sensing structure 122 or the micro sensor 100 may further include other film layers or elements. For example, the micro sensor 100 may further include an insulation layer 130. The insulation layer 130 may be disposed on the first substrate 110 or the second substrate 120. At least part of the insulation layer 130 is located between the first substrate 110 and the second substrate 120, and the at least part of the insulation layer 130 at least covers the surface S with the cavity C and the cavity C. The insulation layer 130 of the present embodiment is disposed, for example, on a surface of the first substrate 110 facing the second substrate 120 and entirely covers the surface, wherein the entire insulation layer 130 is located between the first substrate 110 and the second substrate 120, but the invention is not limited thereto. For example, the insulation layer 130 may also be disposed on a surface of the second substrate 120 facing the first substrate 110.

Additionally, the micro sensor 100 may further includes a first inter-layer dielectric layer 140, a plurality of conductive wires 150, a second inter-layer dielectric layer 160 and a plurality of pads 170. The first inter-layer dielectric layer 140 is disposed on the second substrate 120. The connection portions SS1 and the pressure sensing elements SS2 are located between the first inter-layer dielectric layer 140 and the insulation layer 130. The first inter-layer dielectric layer 140 has a plurality of first openings O1. Each of the first openings O1 exposes a portion of one of the connection portions SS1. The conductive wires 150 are disposed on the first inter-layer dielectric layer 140. A portion of each of the connection portions SS1 is connected with one of the conductive wires 150. The second inter-layer dielectric layer 160 is disposed on the first inter-layer dielectric layer 140 and the conductive wires 150, and the second inter-layer dielectric layer 160 has a plurality of second openings O2. Each of the second openings O2 exposes a portion of one of the conductive wires 150. The pads 170 are disposed on the second inter-layer dielectric layer 160. Each of the pads 170 is connected with the portion of the corresponding conductive wire 150 through one of the second openings O2.

In the present embodiment, a portion of the conductive wires 150 (e.g., conductive wires 152) are connected with two adjacent sensing units U to form a Wheatstone bridge. In addition, another portion of the conductive wires 150 (e.g., conductive wires 154) are respectively connected with one of the conductive wires 152 and the corresponding pad 170. When an external pressure change occurs, the second substrate 120 having the sensing structure 122 is deformed due to a difference between inner and external pressures occurring to the cavity C. In this case, the pressure sensing elements SS2 of the sensing units U at one pair of opposite sides receive an axial compressive stress along a longitudinal axis thereof, while the pressure sensing elements SS2 of the sensing units U at another pair of opposite sides receive an axial tensile stress along a longitudinal axis thereof. Namely, a resistance of the pressure sensing elements SS2 of the sensing units U at one pair of opposite sides is increased, and a resistance of the pressure sensing elements SS2 of the sensing units U at another pair of opposite sides is decreased. By means of the conductive wire 154 outputting an electrical signal varied with the resistance change, the micro sensor 100 may determine the external pressure change by utilizing a signal difference among four sensing units U.

One manufacturing method of the micro sensor 100 will be described with reference to FIGS. 2A to 2K. However, the manufacturing method of the micro sensor 100 is not limited to that illustrated in FIGS. 2A to 2K.

Referring to FIG. 2A, the cavity C is formed on the surface S of the first substrate 100. The first substrate 110 is, for example, a semiconductor substrate, such as a silicon substrate, but the invention is not limited thereto. A method of forming the cavity C includes, for example, photolithography followed by inductively coupled plasma (ICP) etching, but the invention is not limited thereto.

Referring to FIG. 2B, the insulation layer 130 is formed on the first substrate 110. The insulation layer 130 at least covers the surface S with the cavity C and the cavity C. The insulation layer 130 is, for example, an oxide layer, and in this step, the insulation layer 130 covers all surfaces of the first substrate 110, but the invention is not limited thereto.

Referring to FIG. 2C, the surface S of the first substrate 110 with the cavity C is bonded to the second substrate 120 to seal the cavity C, such that the pressure value in the cavity C is a constant value. After the first substrate 110 is bonded to the second substrate 120, at least part of the insulation layer 130 is located between the first substrate 110 and the second substrate 120 to form a silicon on insulator (SOI) structure having the sealed cavity C.

The first substrate 110 and the second substrate 120 are heated and bonded together by means of a heating process, for example. The pressure value in the cavity C is determined based on a pressure during the process. The second substrate 120 is, for example, a semiconductor substrate, such as a silicon substrate, but the invention is not limited thereto. In addition, the second substrate 120 may also be a thinned semiconductor substrate. Alternatively, a thickness H120 of the second substrate 120 may be reduced by means of a thinning process after the first substrate 110 is bonded to the second substrate 120.

Referring to FIG. 2D, before the sensing structure 122 illustrated in FIG. 1 is formed in the second substrate 120, an insulation layer 130A may be formed on the first substrate 120 in advance. The insulation layer 130A is, for example, an oxide layer and merely covers the second substrate 120, but the invention is not limited thereto.

Then, the sensing structure 122 illustrated in FIG. 1 is formed in the second substrate 120. Referring to FIGS. 2E and 2F, a plurality of connection portions SS1 are formed in the second substrate 120, and a plurality of pressure sensing elements SS2 are foamed in the second substrate 120. Each of the pressure sensing elements SS2 is connected with two adjacent connection portions SS1, and orthographic projections of the pressure sensing elements SS2 on the the first substrate 110 fall within a range covered by the cavity C. A method of forming the connection portions SS1 and the pressure sensing elements SS2 includes, for example, ion doping, and a doping concentration of each pressure sensing element SS2 is less than a doping concentration of each connection portion SS1.

Referring to FIG. 2G, the insulation layer 130A and part of the insulation layer 130 are removed, and the insulation layer 130 located between the first substrate 110 and the second substrate 120 remains. A method of removing the insulation layer 130A and part of the insulation layer 130 may include etching, and an etchant may include, for example, a buffered oxide etchant (BOE), but the invention is not limited thereto.

Referring to FIG. 2H, a first inter-layer dielectric layer 140 is formed on the second substrate 120. The connection portions SS1 and the pressure sensing elements SS2 are located between the first inter-layer dielectric layer 140 and the insulation layer 130. The first inter-layer dielectric layer 140 has a plurality of first openings O1. Each of the first openings O1 exposes a portion of one of the connection portions SS1. A method of forming the first inter-layer dielectric layer 140 includes forming a first inter-layer dielectric material layer on the second substrate 120 by means of Plasma Enhanced Chemical Vapor Deposition (PECVD), and then forming the first openings O1 by means of wet etching, but the invention is not limited thereto. A material of the first inter-layer dielectric layer 140 may be silicon oxide, but the invention is not limited thereto.

Referring to FIG. 2I, a plurality of conductive wires 150 are formed on the first inter-layer dielectric layer 140, wherein a portion of each of the connection portions SS1 is connected with one of the conductive wires 150. A method of forming the conductive wires 150 may include forming a conductive layer by means of sputtering, and then patterning the conductive layer by means of dry etching, so as to form the conductive wires 150, but the invention is not limited thereto.

Referring to FIG. 2J, a second inter-layer dielectric layer 160 is formed on the first inter-layer dielectric layer 140 and the conductive wires 150. The second inter-layer dielectric layer 160 has a plurality of second openings O2. Each of the second openings O2 exposes a portion of one of the conductive wires 150. A method of forming the second inter-layer dielectric layer 160 may include forming a second inter-layer dielectric material layer by means of PECVD, and then forming the second openings O2 by means of dry etching, but the invention is not limited thereto. A material of the second inter-layer dielectric layer 160 may be silicon nitride, but the invention is not limited thereto.

Referring to FIG. 2K, a plurality of pads 170 are formed on the second inter-layer dielectric layer 160. Each of the pads 170 is connected with the portion of the corresponding conductive wire 150 through one of the second openings O2. A method of forming the pads 170 may include forming a conductive layer by means of sputtering, and then patterning the conductive layer by means of dry etching, so as to form the pads 170, but the invention is not limited thereto.

In the present embodiment, the insulation layer 130 is formed on the first substrate 110 before the second substrate 120 is bonded to the first substrate 110, while the sensing structure 122 is formed in the second substrate 120 after the second substrate 120 is bonded to the first substrate 110, and the first inter-layer dielectric layer 140, the conductive wires 150, the second inter-layer dielectric layer 160 and the pads 170 are formed on the second substrate 120 after the second substrate 120 is bonded to the first substrate 110, but the invention is not limited thereto. A person ordinarily skilled in the art may change the sequence of the manufacturing process or additionally dispose other elements or film layers, or change shapes of the elements or relative disposition relations, without departing the spirit or scope of the invention. For example, the insulation layer 130 may also be formed on the second substrate 120 before the second substrate 120 is bonded to the first substrate 110. In addition, the sensing structure 122 may be formed on the second substrate 120 before the second substrate 120 is bonded to the first substrate 110. Moreover, the first inter-layer dielectric layer 140, the conductive wires 150, the second inter-layer dielectric layer 160 and the pads 170 may be formed on the second substrate 120 before the second substrate 120 is bonded to the first substrate 110.

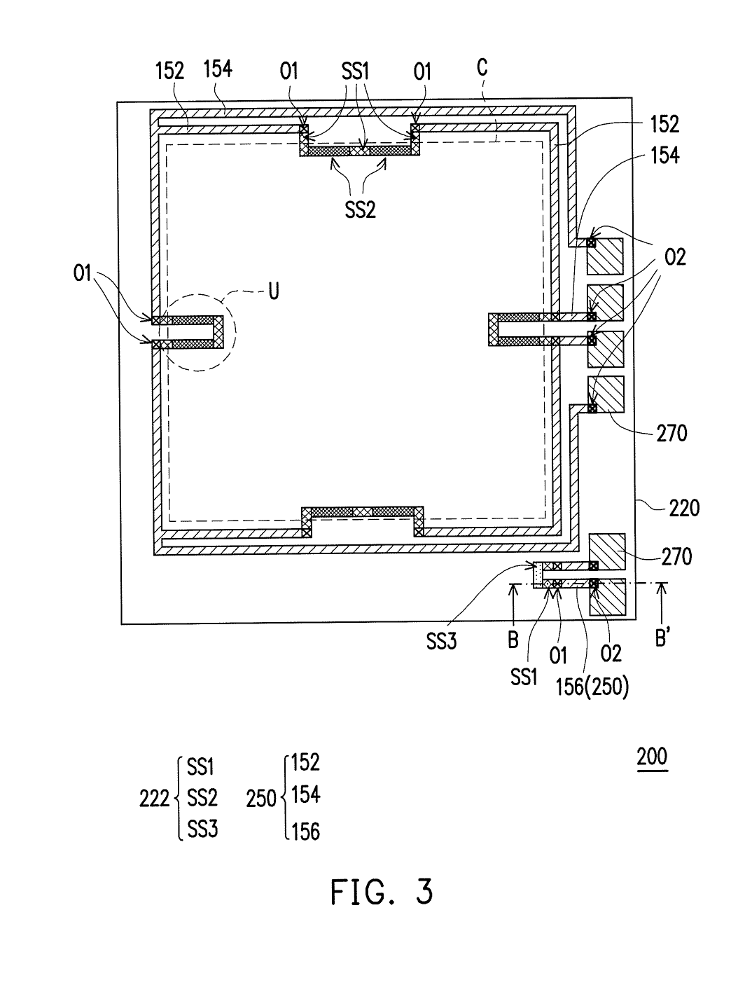

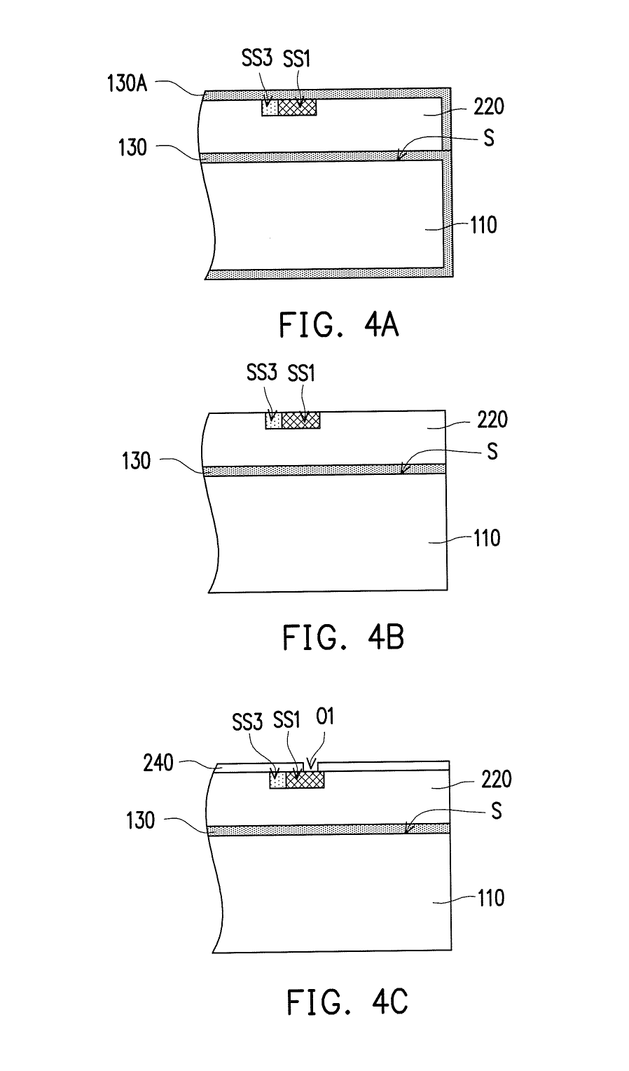

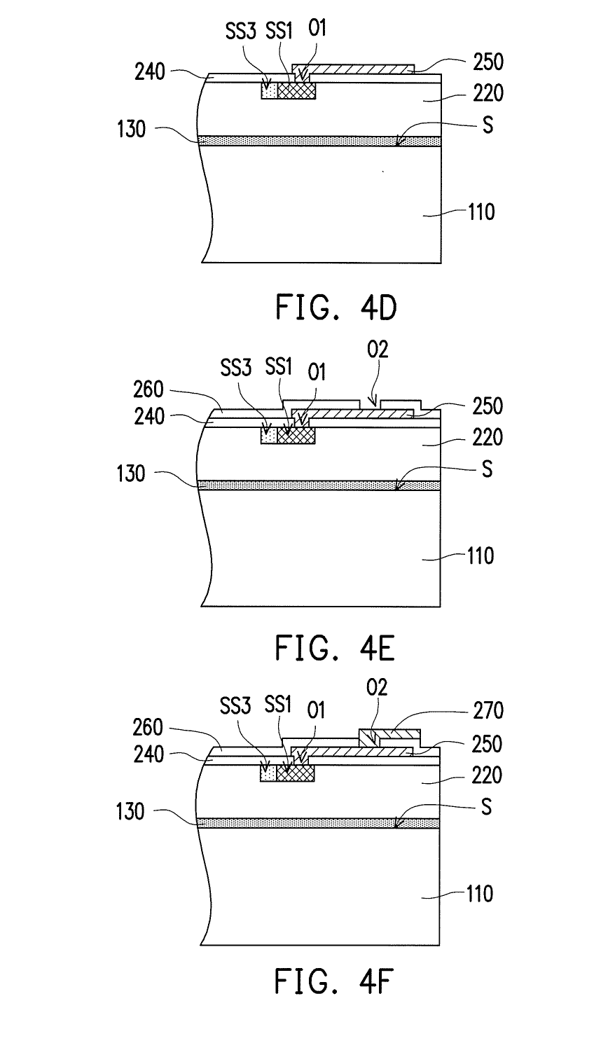

FIG. 3 is a schematic top view of a micro sensor according to another embodiment of the invention. FIGS. 4A to 4F are partial schematic cross-sectional views illustrating a manufacturing process of a micro sensor according to another embodiment of the invention, and the sections illustrated in FIGS. 4A to 4F are corresponding to a section line B-B′ in FIG. 3. In order to illustrate a sensing structure of a micro sensor clearly, part of film layers of the micro sensor are omitted in FIG. 3. Thus, the same or like parts of the specific stacking structure of the micro sensor may refer to FIG. 4 and FIG. 2K.

Referring to FIGS. 3 and 4F first, a micro sensor 200 is similar to the micro sensor 100 illustrated in FIG. 1, and the same elements are labeled by the same reference numbers and will not be repeatedly described. The difference between the micro sensor 200 and the micro sensor 100 mainly lies in that a sensing structure 222 in a second substrate 220 further includes at least one temperature sensing element SS3, in addition to the connection portions SS1 and the pressure sensing elements SS2, for sensing an external temperature change. The temperature sensing element SS3 is connected with the connection portions SS1. Conductive wires 250 include not only the conductive wires 152 and 154, but also a plurality of conductive wires 156. Each of the conductive wires 150 is connected with one of the connection portions SS1 connected with the temperature sensing element SS3 and a corresponding pad 270.

When an external temperature change occurs, a resistance of the temperature sensing element SS3 is correspondingly changed. By means of the conductive wires 156 outputting an electrical signal varied with the resistance change, the micro sensor 200 may determine the external temperature change, so as to compensate influence caused by the temperature to the pressure sensing by means of downstream signal processing.

A manufacturing method of the micro sensor 200 is substantially the same as that of the micro sensor 100. One of the manufacturing methods of the micro sensor 200 will be described with reference to FIGS. 4A to 4F. However, the manufacturing method of the micro sensor 200 is not limited to that illustrated in FIGS. 4A to 4F.

Referring to FIG. 4A and FIG. 3, after the step illustrated in FIG. 2F, a temperature sensing element SS3 may be further formed in the second substrate 220. A method of forming the temperature sensing element SS3 includes, for example, ion doping. As the doping concentration becomes less, the sensitivity to the temperature change is higher, and thus, in the present embodiment, a doping concentration of the temperature sensing element SS3 may be less than or equal to the doping concentration of the pressure sensing element SS2. In other words, in the sensing structure 222, the connection portion SS1 may have the highest doping concentration, and the temperature sensing element SS3 may have the lowest doping concentration. Alternatively, the doping concentrations of the pressure sensing element SS2 and the temperature sensing element SS3 may be the same and lower than the doping concentration of the connection portion SS1.

The steps illustrated in FIGS. 4B to 4F are substantially the same as those illustrated in FIGS. 2H to 2K, and only difference therebetween will be described below. Descriptions related to the same or like parts may refer to the embodiments above and will not be repeated hereinafter.

Referring to FIG. 4B, the insulation layer 130A and part of the insulation layer 130 are removed to expose the temperature sensing element SS3 and the connection portion SS1.

Referring to FIG. 4C and FIG. 3, a first inter-layer dielectric layer 240 is formed on the second substrate 220. The connection portion SS1, the pressure sensing element SS2 and the temperature sensing element SS3 are located between the first inter-layer dielectric layer 240 and the insulation layer 130. The first openings O1 of the first inter-layer dielectric layer 240 expose not only portions of the connection portions SS1 connected with the pressure sensing elements SS2, but also a portion of the connection portion SS1 connected with the temperature sensing element SS3.

Referring to FIG. 4D and FIG. 3, a plurality of conductive wires 250 are formed on the first inter-layer dielectric layer 240, and the conductive wires 250 includes conductive wires 152, 154 and 156. The connection relation of each of the conductive wires 152, 154 and 156 may refer to the descriptions set forth above and will not be repeated hereinafter.

Referring to FIG. 4E and FIG. 3, a second inter-layer dielectric layer 260 is formed on the first inter-layer dielectric layer 240 and the conductive wire 250. The second inter-layer dielectric layer 260 has a plurality of second openings O2. The second openings O2 expose not only portions of the conductive wires 154, but also a portion of the conductive wire 156.

Referring to FIG. 4F and FIG. 3, a plurality of pads 270 are formed on the second inter-layer dielectric layer 260. Each pad 270 is connected with the portion of the corresponding conductive wire 250 through one of the second openings O2. Specifically, each of the pads 270 is connected with the portion of the corresponding conductive wire 154 or 156 through one of the second openings O2.

Based on the above, in the embodiments of the invention, the sealed cavity is formed between the first substrate and the second substrate, and the second substrate having the sensing structure is disposed on the cavity. When an external pressure changes, the second substrate having the sensing structure is deformed due to a difference between inner and external pressures occurring to the cavity, such that the sensing structure can measure different physical quantities. Therefore, micro sensors capable of sensing external pressure changes can be manufactured by the manufacturing method of the micro sensor of the invention, and the micro sensor of the invention is capable of sensing the external pressure changes. In an embodiment, the sensing structure of the micro sensor may further include at least one temperature sensing element in favor of determining external temperature changes, so as to compensate the influence caused by the temperature to the pressure sensing by means of downstream signal processing.

Although the invention has been disclosed by the above embodiments, they are not intended to limit the invention. It will be apparent to one of ordinary skill in the art that modifications and variations to the invention may be made without departing from the spirit and scope of the invention. Therefore, the scope of the invention will be defined by the appended claims.

What is claimed is:

1. A manufacturing method of a micro sensor, comprising:
forming a cavity on a surface of a first substrate;
bonding the surface of the first substrate with the cavity to a second substrate to seal the cavity, such that a pressure value in the cavity is a constant value; and
forming a sensing structure in the second substrate.

2. The manufacturing method of the micro sensor according to claim 1, wherein before bonding the first substrate with the second substrate, the manufacturing method of the micro sensor further comprises:
forming an insulation layer on the first substrate or the second substrate, wherein at least part of the insulation layer is located between the first substrate and the second substrate after the first substrate is bonded to the second substrate, and the at least part of the insulation layer at least covers the surface with the cavity and the cavity.

3. The manufacturing method of the micro sensor according to claim 2, wherein a method of forming the sensing structure in the second substrate comprises:
forming a plurality of connection portions in the second substrate; and
forming a plurality of pressure sensing elements in the second substrate, wherein each of the pressure sensing elements is connected with two adjacent connection portions, and orthographic projections of the pressure sensing elements on the the first substrate fall within a range covered by the cavity.

4. The manufacturing method of the micro sensor according to claim 3, wherein the method of forming the sensing structure in the second substrate further comprises:
forming at least one temperature sensing element in the second substrate, wherein the at least one temperature sensing element is connected with the connection portions.

5. The manufacturing method of the micro sensor according to claim 4, wherein a method of forming the connection portions, the pressure sensing elements and the at least one temperature sensing element comprises ion doping, a doping concentration of each of the pressure sensing elements is less than a doping concentration of each of the connection portions, and the doping concentration of each of the pressure sensing elements is higher than or equal to a doping concentration of the at least one temperature sensing element.

6. The manufacturing method of the micro sensor according to claim 4, wherein after the connection portions, the pressure sensing elements and the at least one temperature sensing element are formed, the manufacturing method of the micro sensor further comprises:
forming a first inter-layer dielectric layer on the second substrate, wherein the connection portions, the pressure sensing elements and the at least one temperature sensing element are located between the first inter-layer dielectric layer and the insulation layer, the first inter-layer dielectric layer has a plurality of first openings, and each of the first openings exposes a portion of one of the connection portions;
forming a plurality of conductive wires on the first inter-layer dielectric layer, wherein the portion of each of the connection portions is connected with one of the conductive wires;
forming a second inter-layer dielectric layer on the first inter-layer dielectric layer and the conductive wires, wherein the second inter-layer dielectric layer has a plurality of second openings, and each of the second openings exposes a portion of one of the conductive wires; and
forming a plurality of pads on the second inter-layer dielectric layer, wherein each of the pads is connected with the portion of the corresponding conductive wire through one of the second openings.

7. A micro sensor, comprising:
a first substrate, having a surface with a cavity; and
a second substrate, having a sensing structure, wherein the surface of the first substrate with the cavity is bonded to the second substrate to seal the cavity, such that a pressure value in the cavity is a constant value.

8. The micro sensor according to claim 7, further comprising:
an insulation layer, disposed on the first substrate or the second substrate, wherein at least part of the insulation layer is located between the first substrate and the second substrate, and the at least part of the insulation layer at least covers the surface with the cavity and the cavity.

9. The micro sensor according to claim 8, wherein the sensing structure comprises a plurality of connection portions and a plurality of pressure sensing elements, each of the pressure sensing elements is connected with two adjacent connection portions, and orthographic projections of the pressure sensing elements on the the first substrate fall within a range covered by the cavity.

10. The micro sensor according to claim 9, wherein the sensing structure further comprises at least one temperature sensing element, and the at least one temperature sensing element is connected with the connection portions.

11. The micro sensor according to claim 10, wherein the connection portions, the pressure sensing elements and the at least one temperature sensing element are formed by means of ion doping, a doping concentration of each of the pressure sensing elements is less than a doping concentration of each of the connection portions, and the doping concentration of each of the pressure sensing elements is higher than or equal to a doping concentration of the at least one temperature sensing element.

12. The micro sensor according to claim 10, further comprising:
a first inter-layer dielectric layer, disposed on the second substrate, wherein the connection portions, the pressure sensing elements and the at least one temperature sensing element are located between the first inter-layer dielectric layer and the insulation layer, the first inter-layer dielectric layer has a plurality of first openings, and each of the first openings exposes a portion of one of the connection portions;
a plurality of conductive wires, disposed on the first inter-layer dielectric layer, wherein the portion of each of the connection portions is connected with one of the conductive wires;
a second inter-layer dielectric layer, disposed on the first inter-layer dielectric layer and the conductive wires, wherein the second inter-layer dielectric layer has a plurality of second openings, each of the second openings exposes a portion of one of the conductive wires; and
a plurality of pads, disposed on the second inter-layer dielectric layer, wherein each of the pads is connected with the portion of the corresponding conductive wire through one of the second openings.
